(19) United States
(12) Patent Application Publication
(10) Pub. No.: US 2025/0038472 A1
(43) Pub. Date: Jan. 30, 2025

(54) OPTICAL TRANSMITTER

(71) Applicant: Nippon Telegraph and Telephone Corporation, Tokyo (JP)

(72) Inventors: Shigeru Kanazawa, Musashino-shi, Tokyo (JP); Takahiko Shindo, Musashino-shi, Tokyo (JP); Meishin Chin, Musashino-shi, Tokyo (JP); Shohei Kosuga, Musashino-shi, Tokyo (JP)

(21) Appl. No.: 18/716,417

(22) PCT Filed: Dec. 7, 2021
(86) PCT No.: PCT/JP2021/044964

§ 371 Date: Jun. 4, 2024

(51) Int. Cl. H01S 5/026; H01S 5/12

(52) U.S. Cl. CPC H01S 5/0265; H01S 5/12

(57) ABSTRACT

Band deterioration due to parasitic inductance of a bonding wire is suppressed. Provided is an optical transmitter in which a chip to which a high frequency signal is applied is mounted on a carrier on which a high frequency wire is formed, and a high frequency signal is supplied to an electrode of the chip via a bump formed on a signal line of the high frequency wire and equal to a height of the chip.

### TECHNICAL FIELD

The present invention relates to an optical transmitter in which a chip to which a high frequency signal is applied is mounted.

### BACKGROUND ART

As a light source of an optical transmitter applied to a next-generation ultrafast optical network, a directly modulated laser (DML) and an electro-absorption modulator integrated with DFB laser (EML) are known. The DML modulates the optical output by directly modulating the current injected into the semiconductor laser (see, for example, Non Patent Literature 1). The EML modulates continuous (CW) light output from a semiconductor laser (LD) by an EA modulator. The EML has an advantage that a large extinction ratio can be obtained and the LD and the EA modulator can be individually optimized as compared with the DML, but since the LD and the EA modulator are integrated in one chip (hereinafter, referred to as an EML chip), the structure is complicated and the producing process is also complicated.

FIG. 1 illustrates a structure of a conventional EML subassembly. FIG. 1(a) is a top view of a portion of an EML subassembly, and FIG. 1(b) is a cross-sectional view along a high frequency wire. In an EML subassembly 10, an EML chip 12 is mounted on a subcarrier 11 on which high frequency wires are integrated. Although not illustrated, a PD for monitoring optical signal intensity, a drive circuit of an LD, an RF circuit for driving and controlling an EA modulator, and the like are mounted on the subcarrier 11. In the EML chip 12, a distributed feedback (DFB) laser and an EA modulator are integrated, and a drive electrode 12a and a modulation electrode 12b are formed on an upper surface of the chip. The high frequency wire is a coplanar line 13 in which grounds 13b and 13c are disposed on both side surfaces of a signal line 13a. The RF circuit that drives and controls the EA modulator supplies a high frequency signal to the modulation electrode 12b via the coplanar line 13 and a bonding wire 14.

The bonding wire 14 is a gold (Au) wire, for example, wedge bonded to the signal line 13a and ball bonded to the modulation electrode 12b, and is wired in a loop shape in consideration of the height of the EML chip 12 in order to prevent sagging therebetween. Therefore, since the gold wire becomes longer according to the height of the EML chip 12, there is a problem that the parasitic inductance increases and the band of the EML deteriorates.

### CITATION LIST

### Non Patent Literature

Non Patent Literature 1: S. Kanazawa et al., “30-km Error-Free Transmission of Directly Modulated DFB Laser Array Transmitter Optical Sub-Assembly for 100-Gb Application,” J. of Lightw. Technol., vol. 34, no. 15, pp. 3646-3652, 2016.

### SUMMARY OF INVENTION

An object of the present invention is to provide an optical transmitter capable of suppressing band deterioration due to parasitic inductance of a bonding wire.

In order to achieve such an object, according to an embodiment of the present embodiment, there is provided an optical transmitter in which a chip to which a high frequency signal is applied is mounted on a carrier on which a high frequency wire is formed, and a high frequency signal is supplied to an electrode of the chip via a bump formed on a signal line of the high frequency wire and at the same height as the chip.

### BRIEF DESCRIPTION OF DRAWINGS

FIG. 1 is a diagram illustrating a structure of a conventional EML subassembly.

FIG. 2 is a diagram illustrating a structure of an EML subassembly according to a first embodiment.

FIG. 3 is a diagram illustrating frequency response characteristics of the EML subassembly according to the first embodiment.

FIG. 4 is a diagram illustrating a structure of an MZM subassembly of a second embodiment.

FIG. 5 is a diagram illustrating frequency response characteristics of the MZM subassembly of the second embodiment.

### DESCRIPTION OF EMBODIMENTS

The following is a detailed description of an embodiment of the present invention with reference to the drawings.

### First Embodiment

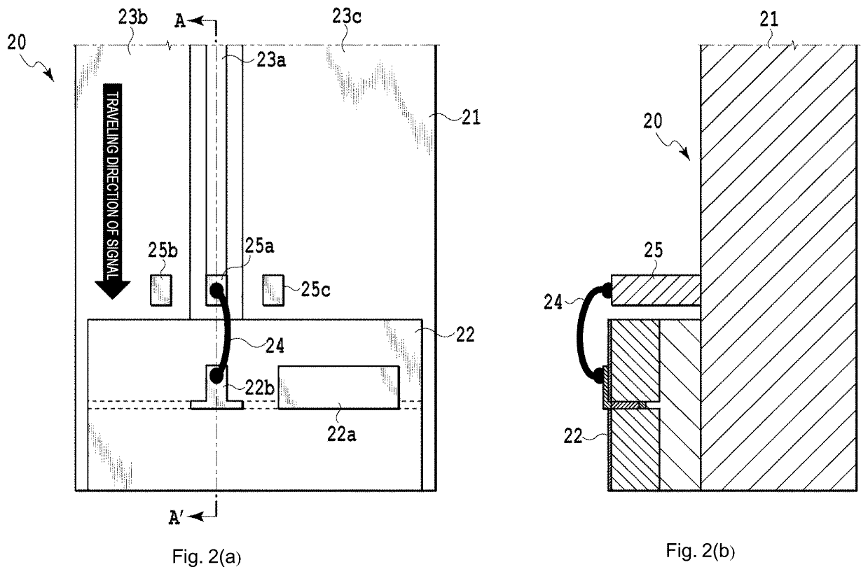

FIG. 2 illustrates a structure of an EML subassembly according to a first embodiment. FIG. 2(a) is a top view of a portion of an EML subassembly, and FIG. 2(b) is a cross-sectional view along a high frequency wire. In an EML subassembly 20, an EML chip 22 is mounted on a subcarrier 21 on which high frequency wires are integrated.

Although not illustrated, a PD for monitoring optical signal intensity, a drive circuit of an LD, an RF circuit for driving and controlling an EA modulator, and the like are mounted on the subcarrier 21. In the EML chip 22, a DFB laser and an EA modulator are integrated, and a drive electrode 22a and a modulation electrode 22b are formed on an upper surface of the chip. The high frequency wire is a coplanar line 23 in which grounds 23b and 23c are disposed on both side surfaces of a signal line 23a.

As illustrated in FIG. 2(a), the signal line 23a of the high frequency wire is formed up to the vicinity of the modulation electrode 22b of the EML chip 22, and a bump 25a is formed at an end portion on the EML chip 22 side. As illustrated in FIG. 2(b), the height of the bump 25a is substantially the same as the height of the EML chip 22. An upper surface of the bump 25a and the modulation electrode 22b are connected by a bonding wire 24. The RF circuit that drives and controls the EA modulator supplies a high frequency signal to the modulation electrode 22b via the coplanar line 23, the bump 25a, and the bonding wire 24.

With such a configuration, the length of the bonding wire 24 can be shortened by the height of the EML chip 22. Therefore, the parasitic inductance can be reduced, and the band as the EML can be improved.

In the first embodiment, a grounded-coplanar line is shown, but it is obvious that the present invention can also be applied to a microstrip line having no ground on both side surfaces of a signal line. In the case of the coplanar line, if the bumps 25b and 23c are further formed on the grounds 23b and 25c on both side surfaces of the bump 25a, a high frequency line approximating the characteristic impedance of the coplanar line is formed, and band deterioration can be further suppressed.

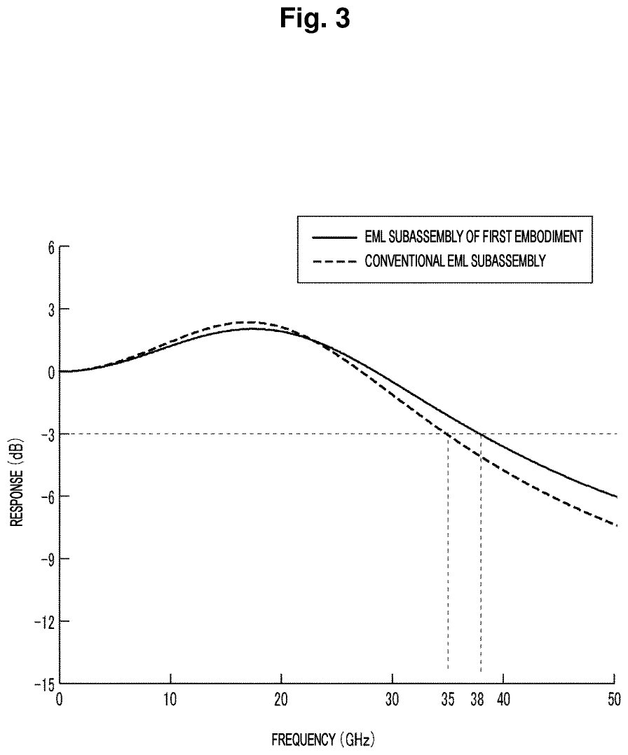

FIG. 3 illustrates frequency response characteristics of the EML subassembly according to the first embodiment. The EML subassembly 20 illustrated in FIG. 2 was produced. The height of the EML chip 22 and the height of the bump 25a were set to 0.15 mm. The shape of the bumps 25a to 25c is a prism of 0.07 mm square. The bumps 25a to 25c are formed by copper plating, and have a structure in which the surface is gold-plated. As the bonding wire 24, a gold wire having a diameter of 0.025 mm was used. A gap between the bump 25a and the bumps 25b and 25c was set to 0.03 mm, and the characteristic impedance was set to 50Ω similarly to the coplanar line 23.

Note that the shape of the bump has been described by exemplifying a prism, but the bump may have another shape such as a cylindrical shape. The bump may have any shape as long as it has the same height as the chip, can obtain the characteristic impedance of the high frequency wire, and can bond the bonding wire to the upper surface. In addition, the bump can be produced by a bump bonder, but can also be realized by using plating or mounting a block material obtained by processing metal, and the material and the producing method are not limited.

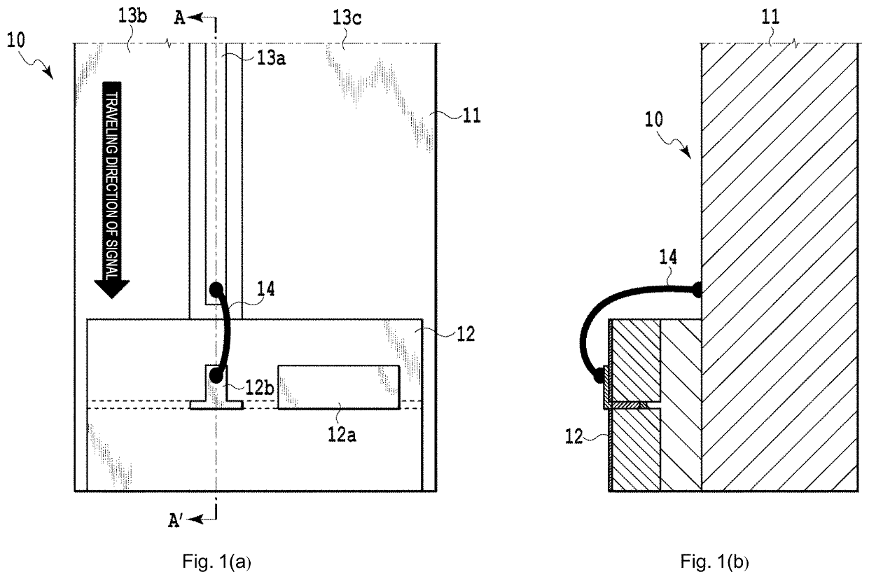

The conventional EML subassembly 10 as illustrated in FIG. 1 was also produced to compare frequency response characteristics. In the conventional EML subassembly 10, the 3 dB band is about 35 GHZ, but in the EML subassembly 20 of the first embodiment, the 3 dB band can be improved to 38 GHz. For example, in a case of applying to an ultrahigh-speed optical network with a baud rate of 50 Gbaud of a modulated signal, a band of 35 GHz or more, which is about 0.7 times the baud rate, is required. Although the conventional EML subassembly meets this requirement but has no bandwidth to spare, according to the EML subassembly of the first embodiment, it is possible to realize an optical transmitter that satisfies the requirement with a sufficient margin.

### Second Embodiment

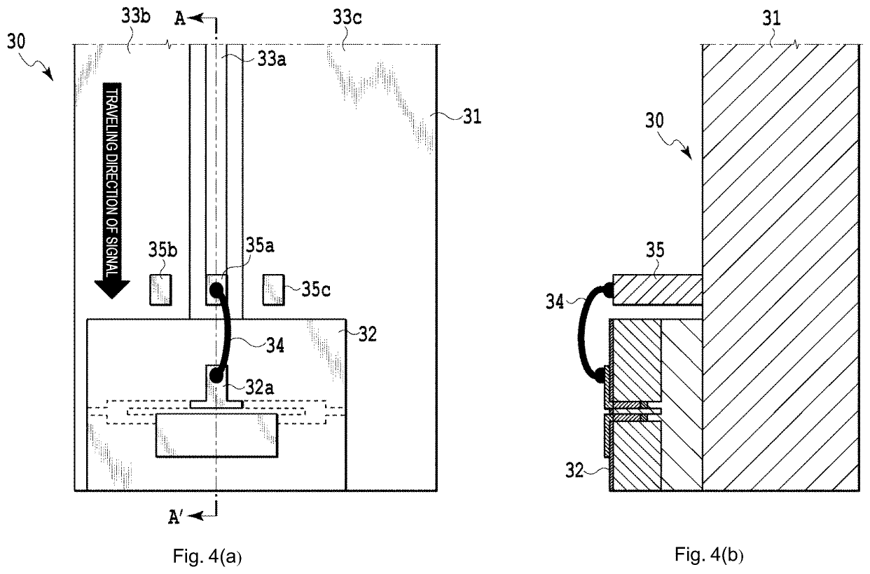

FIG. 4 illustrates a structure of an MZM subassembly according to a second embodiment. In the first embodiment, the EML as the light source of the optical transmitter has been described as an example, but in the second embodiment, a subassembly of a single optical modulator will be described as an example. A Mach-Zehnder interferometer modulator (MZM) is used as the optical modulator.

FIG. 4(a) is a top view of a portion of the MZM subassembly, and FIG. 4(b) is a cross-sectional view along a high frequency wire. In an MZM subassembly 30, an MZM chip 32 is mounted on a subcarrier 31 on which high frequency wires are integrated. Although not illustrated, a PD for monitoring optical signal intensity, an RF circuit for driving and controlling the MZM, and the like are mounted on the subcarrier 31. The MZM chip 32 has two arm waveguides as a Mach-Zehnder interferometer, and a modulation electrode 32a formed in one arm waveguide is formed on an upper surface of the chip. The high frequency wire is a coplanar line 33 in which grounds 33b and 33c are disposed on both side surfaces of a signal line 33a.

As illustrated in FIG. 4(a), the signal line 33a of the high frequency wire is formed up to the vicinity of the modulation electrode 32a of the MZM chip 32, and a bump 35a is formed at an end portion on the MZM chip 32 side. As illustrated in FIG. 4(b), the height of the bump 35a is substantially the same as the height of the MZM chip 32. An upper surface of the bump 35a and the modulation electrode 32a are connected by a bonding wire 34. The RF circuit that drives and controls the MZM supplies a high frequency signal to the modulation electrode 32a via the coplanar line 33, the bump 35a, and the bonding wire 34.

With such a configuration, the length of the bonding wire 34 can be shortened by the height of the MZM chip 32. Therefore, the parasitic inductance can be reduced, and the band as the MZM can be improved.

Further, the bumps 35b and 33c are also formed on the grounds 33b and 35c on both side surfaces of the bump 35a. A high frequency line approximating a coplanar line is formed, and band deterioration can be further suppressed.

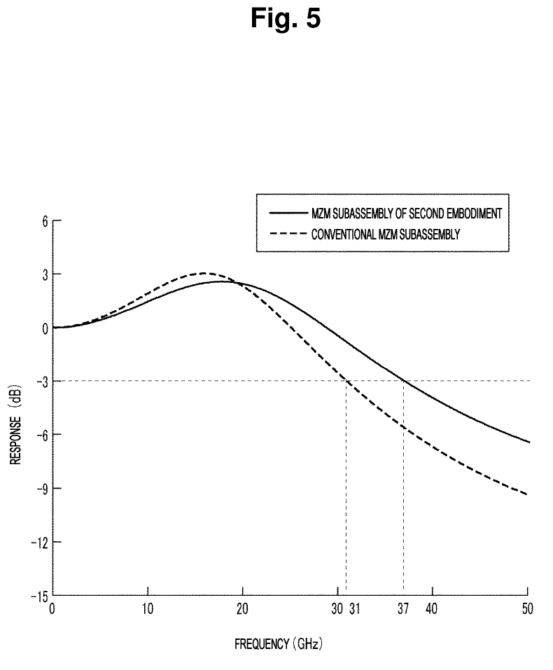

FIG. 5 illustrates frequency response characteristics of the MZM subassembly according to the second embodiment. The MZM subassembly 30 illustrated in FIG. 4 was produced. The height of the MZM chip 32 and the height of the bump 35a were set to 0.2 mm. The shape of the bumps 35a to 35c is a prism of 0.1 mm square. The bumps 25a to 25c are formed by mounting a metal block in which the surface of the Kovar is gold-plated by solder. As the bonding wire 34, a gold wire having a diameter of 0.025 mm was used. A gap between the bump 35a and the bumps 35b and 35c was set to 0.045 mm, and the characteristic impedance was set to 50Ω similarly to the coplanar line 33.

As in the first embodiment, a conventional MZM subassembly without a bump mounted on a high frequency line was also produced, and the frequency response characteristics were compared. In the conventional MZM subassembly, the 3 dB band is about 31 GHz, but in the MZM subassembly 30 of the second embodiment, the 3 dB band can be improved to 37 GHz. For example, in a case of applying to an ultrahigh-speed optical network with a baud rate of 50 Gbaud of a modulated signal, a band of 35 GHz or more, which is about 0.7 times the baud rate, is required. Although the conventional MZM subassembly cannot meet this requirement, the MZM subassembly of the first embodiment can realize an optical transmitter that meets this requirement.

In the first and second embodiments, in the optical transmitter in which the chip to which the high frequency signal is applied is mounted on the carrier on which the high frequency wire is formed, the high frequency signal is supplied to the electrode of the chip via the bump formed on the high frequency wiring and equal to the height of the chip. With such a configuration, it is possible to suppress band deterioration due to parasitic inductance of the bonding wire, and further, it is possible to suppress band deterioration of the optical transmitter in which these chips are mounted.

Although the EML chip and the MZM chip have been described as examples of the chip mounted on the carrier, the present embodiment is not limited thereto, and can be applied to an optical transmitter in which a chip to which a high frequency signal is applied, such as the above-described DML chip, is mounted.

1. An optical transmitter in which a chip to which a high frequency signal is applied is mounted on a carrier on which a high frequency wire is formed, wherein a high frequency signal is supplied to an electrode of the chip via a bump formed on a signal line of the high frequency wire and having the same height as the chip.

2. The optical transmitter according to claim 1, wherein the high frequency wire is a microstrip line or a grounded-coplanar line.

3. The optical transmitter according to claim 1, wherein the high frequency wire is a grounded-coplanar line, and bumps are formed on the ground on both side surfaces of the signal line on which the bumps are formed.

4. The optical transmitter according to claim 1, wherein the chip is an electro-absorption modulator integrated with a DFB laser, a Mach-Zehnder interferometer type optical modulator, or a directly modulated laser.

5. The optical transmitter according to claim 4, wherein baud rates of modulation signals of the electro-absorption modulator integrated with a DFB laser and the Mach-Zehnder interferometer type optical modulator are 50 Gbaud or more.

6. The optical transmitter according to claim 2, wherein the chip is an electro-absorption modulator integrated with a DFB laser, a Mach-Zehnder interferometer type optical modulator, or a directly modulated laser.

7. The optical transmitter according to claim 3, wherein the chip is an electro-absorption modulator integrated with a DFB laser, a Mach-Zehnder interferometer type optical modulator, or a directly modulated laser.
